(19) United States
(12) Patent Application Publication
(10) Pub. No.: US 2026/0197980 A1
(43) Pub. Date: Jul. 9, 2026

(54) COOLANT CONTROL UNIT, COOLING DISTRIBUTION SYSTEM, AND CONTROL METHOD THEREOF

(71) Applicant: LITE-ON TECHNOLOGY CORPORATION, Taipei (TW)

(72) Inventors: Chih-Fang WANG, Taipei (TW); Tzu-Cheng FANG, Taipei (TW); Yung-Chang CHIU, Taipei (TW); Chih-Chueh LIN, Taipei (TW)

(21) Appl. No.: 19/375,301

(22) Filed: Oct. 31, 2025

Related U.S. Application Data
(60) Provisional application No. 63/742,888, filed on Jan. 8, 2025.

(30) Foreign Application Priority Data
Apr. 29, 2025 (CN) 202510552044.3

(51) Int. Cl. H05K 7/20

(52) U.S. Cl. CPC H05K 7/20836; H05K 7/2079

(57) ABSTRACT

A coolant control unit controls a liquid cooling device to cool a target device. The coolant control unit includes a first pump system and a second pump system. The first pump system is coupled to a bus of a CAN type, and transmits or receives a first bus signal via the bus. A first pump of the first pump system causes a coolant of the liquid cooling device to have a first hydraulic pressure. The second pump system is coupled to the first pump system via the bus, and transmits or receives a second bus signal via the bus. A second pump of the second pump system causes the coolant to have a second hydraulic pressure. The first bus signal and the second bus signal respectively indicate an abnormal state of the first pump system and an abnormal state of the second pump system.

This application claims the benefit of US provisional application Serial No. 63/742,888, filed Jan. 08, 2025, and CN application Serial No. 202510552044.3, filed Apr. 29, 2025, the disclosures of which are incorporated by reference herein in its entirety.

### TECHNICAL FIELD

The present disclosure relates to a cooling mechanism, and more particularly relates to a coolant control unit and a control method for a liquid cooling device applied to a data center.

### BACKGROUND

To meet the resource requirements of massive computations for artificial intelligence, we have to dispose data centers to provide storage for massive amounts of data. When executing massive amounts of AI computations, hardware components in data centers may generate huge heat. Therefore, an effective cooling mechanism must be provided for the data centers.

Among various types of cooling mechanisms, liquid cooling is the mainstream method. In the liquid cooling method, a coolant control unit is employed to control the liquid cooling device, so as to adjust various parameters of the coolant in the liquid cooling device (such as the hydraulic pressure, the liquid temperature, and the flow rate, etc.). In order to maintain stable operation of the liquid cooling device to achieve sufficient cooling efficiency, the fluid stability of the coolant is a key issue.

The fluid stability of the coolant depends on whether the coolant control unit and the pump system of the liquid cooling device can operate normally. If the pump system malfunctions and fails to return to a normal state in a timely manner, it will cause an imbalance on the fluid stability of the coolant (for example, the flow of the coolant will be unstable), thereby reducing the cooling efficiency of the liquid cooling device. This will cause the hardware components of the data centers to experience an overheat condition.

In view of the above issues, it is desirable to have an improved coolant control unit that is capable of promptly detecting abnormalities in the pump system, and restoring the normal operation of the pump system in a timely manner, so as to maintain the fluid stability of the coolant.

### SUMMARY

According to one embodiment of the present disclosure, a coolant control unit is provided. The coolant control unit is for controlling a liquid cooling device to cool a target device. The coolant control unit includes a first pump system and a second pump system. The first pump system is coupled to a bus of a Controller-Area-Network (CAN) type, and for transmitting or receiving a first bus signal via the bus, wherein a first pump of the first pump system causes a coolant of the liquid cooling device to have a first hydraulic pressure. The second pump system is coupled to the first pump system via the bus, and for transmitting or receiving a second bus signal via the bus, wherein a second pump of the second pump system causes the coolant to have a second hydraulic pressure. The first bus signal and the second bus signal respectively indicate an abnormal state of the first pump system and an abnormal state of the second pump system.

According to another embodiment of the present disclosure, a cooling distribution system is provided. The cooling distribution system includes a first coolant control unit and a second coolant control unit. The first coolant control unit is coupled to an external bus of a Controller-Area-Network (CAN) type. The second coolant control unit is coupled to the first coolant control unit via the external bus. The first coolant control unit and the second coolant control unit have an identical structure.

According to still another embodiment of the present disclosure, a control method is provided. The control method is applied to a coolant control unit. The coolant control unit controls a liquid cooling device to cool a target device, a first pump system of the coolant control unit is coupled to a bus of a Controller-Area-Network (CAN) type, and a second pump system of the coolant control unit is coupled to the first pump system via the bus. The control method includes the following steps. Pressurizing a coolant of the liquid cooling device by a first pump of the first pump system to cause the coolant has a first hydraulic pressure. Pressurizing the coolant by a second pump of the second pump system to cause the coolant has a second hydraulic pressure. Transmitting or receiving a first bus signal via the bus by the first pump system. Transmitting or receiving a second bus signal via the bus by the second pump system. The first bus signal and the second bus signal respectively indicate an abnormal state of the first pump system and an abnormal state of the second pump system.

### BRIEF DESCRIPTION OF THE DRAWINGS

FIG. 1 is a block diagram of a pump system 100a and a sensing module 200a according to an embodiment of the present disclosure.

FIG. 2 is a block diagram of a fan system 2001 according to an embodiment of the present disclosure.

FIG. 3 is a block diagram of a coolant control unit 1000 according to an embodiment of the present disclosure.

FIG. 4 is a schematic diagram of a liquid cooling device 2000 according to an embodiment of the present disclosure.

FIG. 5 is a flow chart of a control method according to an embodiment of the present disclosure.

FIG. 6 is a block diagram of a cooling distribution system 3000 according to an embodiment of the present disclosure.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

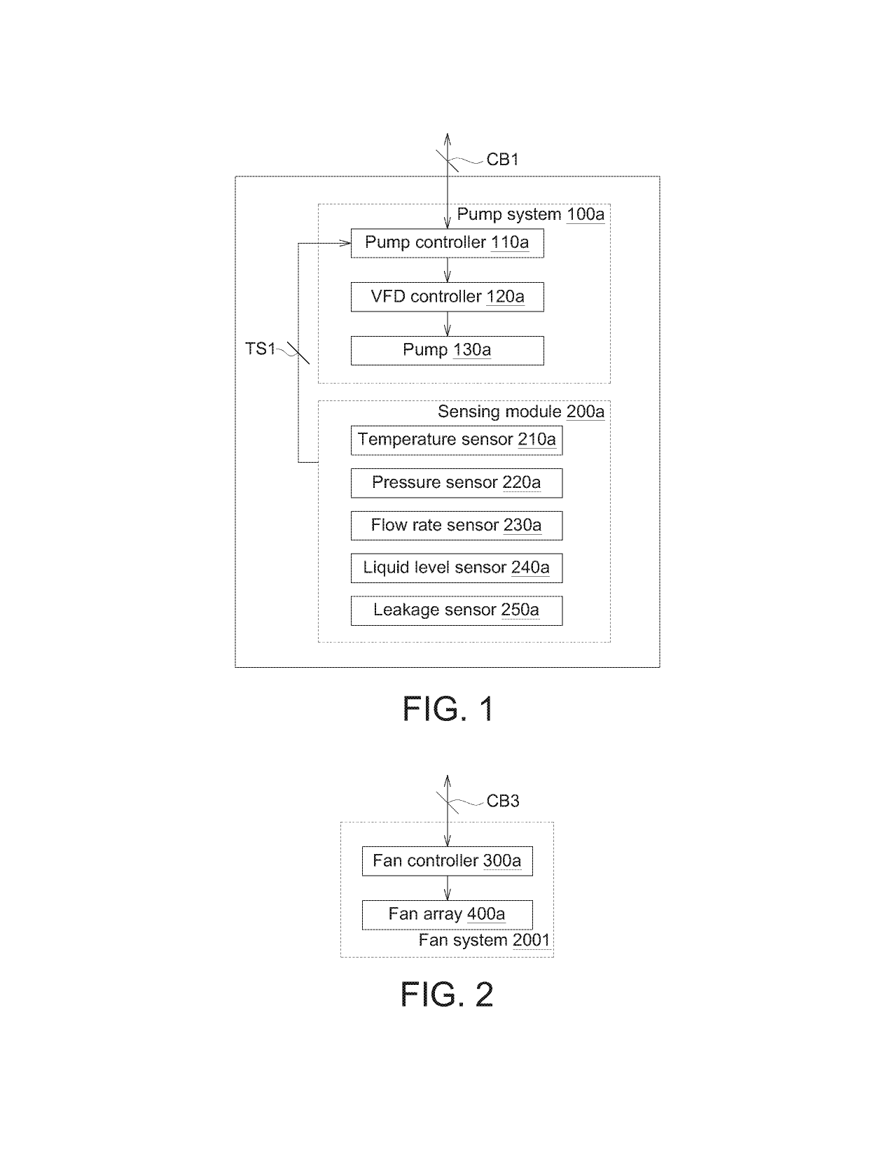

FIG. 1 is a block diagram of a pump system 100a and a sensing module 200a according to an embodiment of the present disclosure. As shown in FIG. 1, the pump system 100a includes a pump controller 110a, a variable frequency drive (VFD) controller 120a and a pump 130a. In operation, the pump controller 110a controls the pump 130a to apply pressure to the coolant, so that the coolant has a predetermined hydraulic pressure in the pipeline of the liquid cooling device (the liquid cooling device is not shown in FIG. 1), thereby causing the coolant to reach a predetermined flow rate or a predetermined flow velocity. The coolant is supplied to a target device (the target device is not shown in FIG. 1), so as to decrease the temperature of the target device by liquid cooling. Furthermore, the pump controller 110a transmits or receives a bus signal CB1 via a bus (the bus is not shown in FIG. 1). The bus signal CB1 may include information related to the operating state of the pump 130a (including a normal state and an abnormal state).

On the other hand, the sensing module 200a includes a temperature sensor 210a, a pressure sensor 220a, a flow rate sensor 230a, a liquid level sensor 240a and a leakage sensor 250a. In operation, the temperature sensor 210a is used to detect the temperature of the coolant (referred to as "liquid temperature"), the pressure sensor 220a is used to detect the pressure of the coolant (referred to as "hydraulic pressure"), the flow rate sensor 230a is used to detect the flow rate and flow velocity of the coolant, the liquid level sensor 240a is used to detect the liquid level of the coolant in the water tank, and the leakage sensor 250a is used to detect the leakage status of the coolant when it flows in the pipelines of the liquid cooling device.

The sensing results for the liquid temperature, hydraulic pressure, flow rate, liquid level and leakage status obtained by the temperature sensor 210a, the pressure sensor 220a, the flow rate sensor 230a, the liquid level sensor 240a and the leakage sensor 250a can be integrated into a sensing signal TS1. The sensing module 200a generates the afore-mentioned sensing signal TS1, and provides the sensing signal TS1 to the pump controller 110a of the pump system 100a. The pump controller 110a obtains the liquid temperature, hydraulic pressure, flow rate, liquid level and leakage status of the coolant according to the sensing signal TS1. The pump controller 110a adjusts the rotational speed of the motor inside the pump 130a accordingly in response to the sensing signal TS1, thereby adjusting the pressure applied to the coolant. In one example, the information included in the sensing signal TS1 of the sensing module 200a may also be integrated into the bus signal CB1 transmitted by the pump controller 110a.

FIG. 2 is a block diagram of a fan system 2001 according to an embodiment of the present disclosure. The fan system 2001 cooperates with the pump system 100a of FIG. 1. For example, the pump system 100a can indirectly or directly control the fan system 2001 to provide a suitable airflow, so as to perform air-cooling on the coolant which flows through a radiator (the radiator is not shown in FIG. 2) in the liquid cooling device. In other embodiments, the pump system 100a of FIG. 1 may further cooperate with a plurality of fan systems (each having a hardware architecture identical to that of the fan system 2001 of FIG. 2), so as to perform air-cooling.

More specifically, as shown in FIG. 2, the fan system 2001 includes a fan controller 300a and a fan array 400a. The fan array 400a includes a plurality of fans (the fans are not shown in FIG. 2). In operation, the fan controller 300a is used to control the rotational speed of the fans in the fan array 400a, so that the fans achieve a suitable airflow to decrease the temperature of the coolant flowing through the radiator (there may be several ones of fan system 2001, which is not limited to the above description or figures).

The fan controller 300a can transmit or receive a bus signal CB3 via a bus (the bus is not shown in FIG. 2). In one example, the bus signal CB3 may be provided to the pump controller 110a of the pump system 100a of FIG. 1 via the bus. The pump controller 110a may obtain information related to the rotational speed (or other parameters) of the fans of the fan array 400a according to the bus signal CB3.

In contrast, the bus signal CB1 transmitted by the pump controller 110a of FIG. 1 can also be provided to the fan controller 300a via the bus. The pump controller 110a may command the fan controller 300a to perform corresponding control on the fans of the fan array 400a via the bus signal CB1.

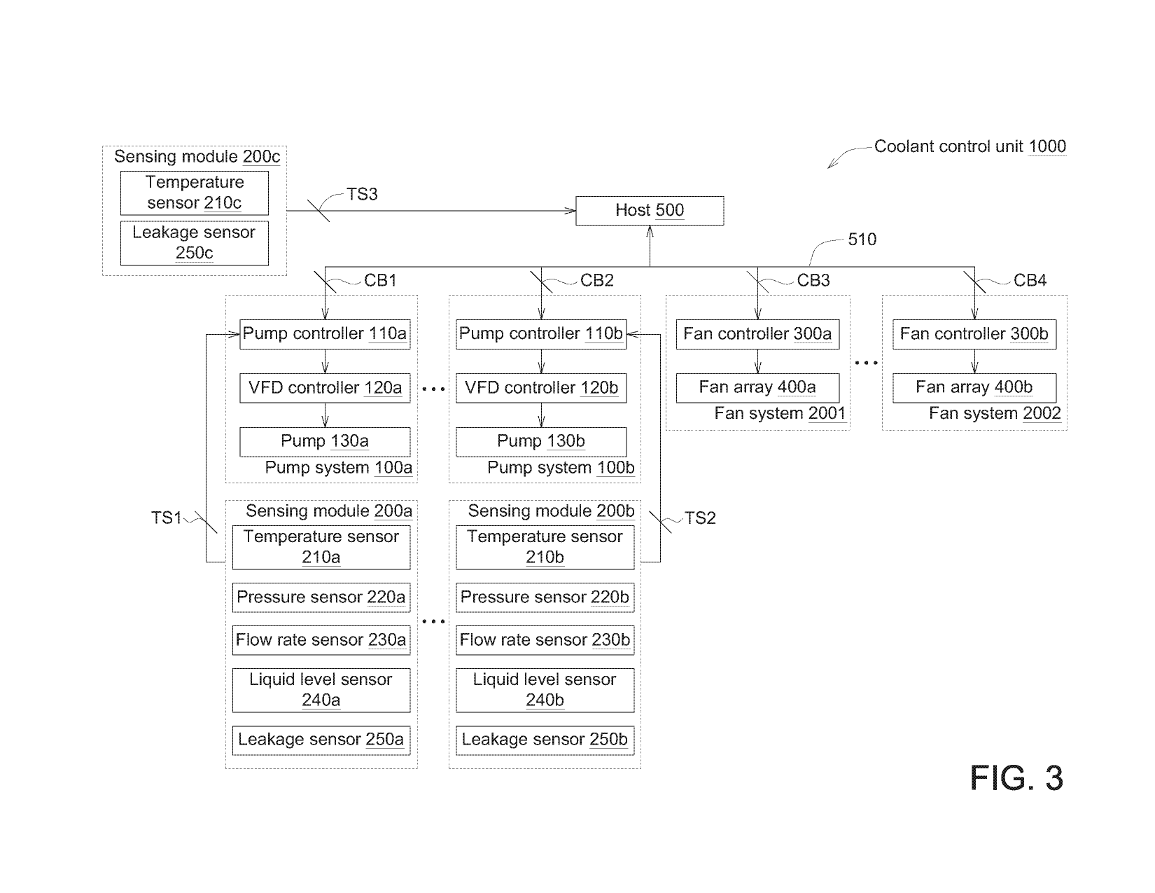

FIG. 3 is a block diagram of a coolant control unit 1000 according to an embodiment of the present disclosure. As shown in FIG. 3, the coolant control unit 1000 includes a host 500, a fan system 2001, a fan system 2002, a first set of pump system 100a and a sensing module 200a, and a second set of pump system 100b and a sensing module 200b. The fan system 2001 corresponds to the first set of pump system 100a and sensing module 200a, and the fan system 2002 corresponds to the second set of pump system 100b and sensing module 200b (the embodiment of FIG. 3 only shows two sets of pump systems, sensing modules and fan systems, but is not limited thereto. The coolant control unit 1000 may also include more than two sets of pump systems, sensing modules and fan systems).

The architecture of the second set of pump system 100b is similar to that of the first set of pump system 100a. The pump system 100b includes a pump controller 110b, a VFD controller 120b and a pump 130b. The pump system 100b generates a bus signal CB2, and transmits or receives the bus signal CB2 via the bus 510.

Furthermore, the architecture of the second set of sensing module 200b is similar to that of the first set of sensing module 200a. The sensing module 200b includes a temperature sensor 210b, a pressure sensor 220b, a flow rate sensor 230b, a liquid level sensor 240b and a leakage sensor 250b. The sensing module 200b generates a sensing signal TS2 and provides the sensing signal TS2 to the pump controller 110b. The sensing signal TS2 integrates respective sensing results of the temperature sensor 210b, the pressure sensor 220b, the flow rate sensor 230b, the liquid level sensor 240b and the leakage sensor 250b.

The first set of pump system 100a and sensing module 200a, the second set of pump system 100b and sensing module 200b, and fan system 2001 and fan system 2002 are communicatively coupled to the host 500 via a bus 510. The pump controller 110a provides a bus signal CB1, the pump controller 110b provides a bus signal CB2, the fan controller 300a provides a bus signal CB3, and the fan controller 300b provides a bus signal CB4. The bus signals CB1, CB2, CB3 and CB4 are transmitted to the host 500 via the bus 510. Furthermore, the bus signals CB1, CB2, CB3 and CB4 may also be transmitted among one another of the pump controller 110a, the pump controller 110b, the fan controller 300a and the fan controller 300b via the bus 510.

In addition, the host 500 is further coupled to the sensing module 200c. The architecture of the sensing module 200c is similar to that of the first set of sensing module 200a, but the sensing module 200c only includes a temperature sensor 210c and a leakage sensor 250c (i.e., the sensing module 200c does not include a pressure sensor, a flow rate sensor and a liquid level sensor). In this embodiment, the sensing module 200c is directly coupled to the host 500. The sensing module 200c is not coupled to the bus 510. The sensing signal TS3 generated by the sensing module 200c may be directly transmitted to the host 500 without being transmitted via the bus 510.

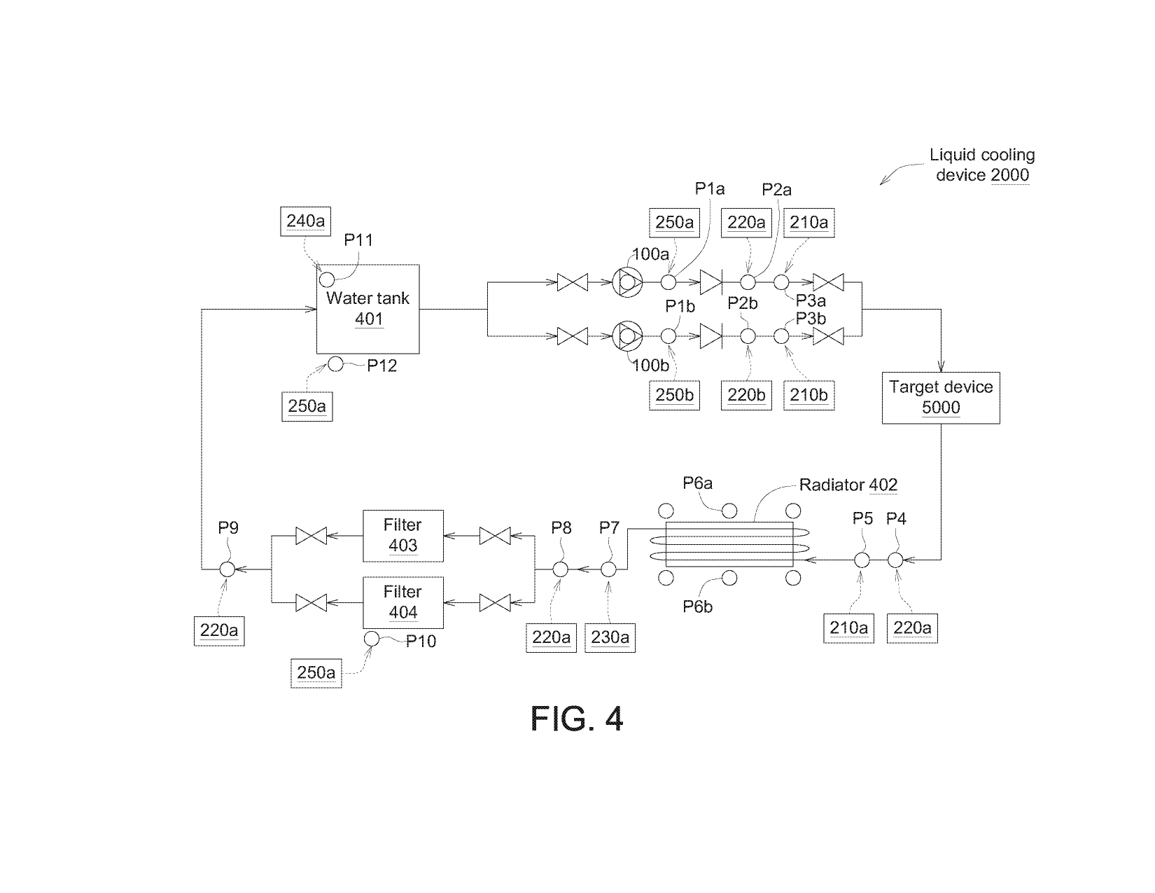

The coolant control unit 1000 is used to control the operation of a liquid cooling device (the liquid cooling device is not shown in FIG. 3) to cool a target device (the target device is not shown in FIG. 3). The operation of the liquid cooling device controlled by the coolant control unit 1000 is described in detail in FIG. 4 below.

FIG. 4 is a schematic diagram of a liquid cooling device 2000 according to an embodiment of the present disclosure. The liquid cooling device 2000 provides the coolant to the target device 5000, so as to cool the target device 5000 by liquid cooling. The target device 5000 is, for example, a hardware component in a data center. As shown in FIG. 4, the liquid cooling device 2000 includes a water tank 401, a radiator 402, and two filters 403 and 404. The coolant control unit 1000 of FIG. 3 controls the liquid cooling device 2000. The pump system 100a and the pump system 100b of the coolant control unit 1000 are disposed in the liquid cooling device 2000. For example, the outlet of the water tank 401 has two pipelines, the pump system 100a is disposed in a first pipeline, and the pump system 100b is disposed in a second pipeline.

In operation, the water tank 401 is used to store the coolant. The coolant is provided to the pump system 100a via the first pipeline, and is provided to the pump system 100b via the second pipeline. The pump 130a of the pump system 100a and the pump 130b of the pump system 100b each may apply pressure to the coolant, so that the coolant has a predetermined hydraulic pressure, thereby achieving a predetermined flow rate or a predetermined flow velocity. The pressurized coolant is provided to the target device 5000, so as to cool the target device 5000.

The coolant returns from the target device 5000 and enters the radiator 402. The fans of the fan system 2001 and the fan system 2002 of the coolant control unit 1000 of FIG. 3 provide temperature reduction for the radiator 402 by air cooling. Therefore, the liquid temperature of the coolant flowing through the radiator 402 can be reduced. Then, the cooled coolant enters the filter 403 and the filter 404 for filtration. After filtration, the coolant, returns to the water tank 401.

In a cyclical manner, the coolant that returns to the water tank 401 is again transmitted to the pump system 100a and the pump system 100b via the first pipeline and the second pipeline for pressurization. The pressurized coolant is provided to the target device 5000 for cooling.

More specifically, the liquid cooling device 2000 is provided with several sensing points P1a~P12. Parameters or characteristics of the liquid cooling device 2000 associated with these sensing points P1a to P12 may be detected (or obtained) by the temperature sensor 210a, pressure sensor 220a, flow rate sensor 230a, liquid level sensor 240a and leakage sensor 250a of the sensing module 200a and the temperature sensor 210b, pressure sensor 220b, flow rate sensor 230b, liquid level sensor 240b and leakage sensor 250b of the sensing module 200b of the coolant control unit 1000 in FIG. 3.

For example, a sensing point P2a is disposed at the outlet of the pump 130a of the pump system 100a at the first pipeline, and the pressure sensor 220a performs sensing based on the sensing point P2a, so as to detect the hydraulic pressure of the coolant at the outlet of the pump 130a. Similarly, a sensing point P2b is disposed at the outlet of the pump 130b of the pump system 100b at the second pipeline, and the pressure sensor 220b performs sensing based on the sensing point P2b, so as to detect the hydraulic pressure of the coolant at the outlet of the pump 130b. In other words, the coolant control unit 1000 detects the hydraulic pressure of the coolant at the outlets of the two independent pumps 130a and 130b respectively using the two independent pressure sensors 220a and 220b. According to respective sensing results of the pressure sensor 220a and the pressure sensor 220b, the pump controller 110a of the pump system 100a can adjust the pressure applied by the pump 130a to the coolant flowing through the first pipeline. Similarly, the independent pump controller 110b of another pump system 100b adjusts the hydraulic pressure of the coolant in the second pipeline of the pump 130b. Accordingly, the hydraulic pressure of the coolant in the first and second pipelines can be balanced and made approximately equal, thereby stabilizing the load pressure of the two independent pumps 130a and 130b.

In addition, a sensing point P3a is provided at the outlet of the pump 130a of the pump system 100a at the first pipeline. The temperature sensor 210a detects the liquid temperature of the coolant at the first pipeline according to the sensing point P3a. Similarly, a sensing point P3b is further provided at the outlet of the pump 130b of the pump system 100b at the second pipeline. The temperature sensor 210b detects the liquid temperature of the coolant at the second pipeline according to the sensing point P3b. In addition, the pump 130a of the pump system 100a and the pump 130b of the pump system 100b are equipped with other temperature sensors (not shown) for sensing temperature of the pump itself, so as to prevent the pump from overheating.

Sensing points P4 and P5 are disposed in the pipeline where the coolant returns from the target device 5000. The sensing points P4 and P5 are disposed between the target device 5000 and the radiator 402. The coolant control unit 1000 detects the hydraulic pressure of the coolant at the sensing point P4 using the pressure sensor 220a, and cooperates with the hydraulic pressure sensing results obtained by the pressure sensor 220a and the pressure sensor 220b at the sensing point P2a and the sensing point P2b respectively, and then calculates the pressure difference of the hydraulic pressures between the sensing point P4, the sensing point P2a and the sensing point P2b according to the respective hydraulic pressure sensing results of the sensing point P4, the sensing point P2a and the sensing point P2b, so as to control the pressure of the pump 130a and the pump 130b accordingly (for example, controlling the pump 130a and the pump 130b, so as to make the hydraulic pressure of the output coolant therefrom, to reach the same pressure). The coolant control unit 1000 detects the temperature of the coolant according to the sensing point P5 via the temperature sensor 210a. Furthermore, the radiator 402 is provided with sensing points P6a and P6b for sensing the air temperature.

Sensing points P7 and P8 are disposed at the pipeline between the radiator 402 and the filters 403 and 404. The coolant control unit 1000 detects the hydraulic pressure of the coolant at the sensing point P8 using the pressure sensor 220a, and detects the flow rate of the coolant at the sensing point P7 using the flow rate sensor 230a.

A sensing point P9 is disposed at the pipeline between the filters 403 and 404 and the water tank 401. The coolant control unit 1000 detects the hydraulic pressure of the coolant at the sensing point P9 via the pressure sensor 220a. Furthermore, a sensing point P11 is disposed inside the water tank 401, and the coolant control unit 1000 detects the liquid level of the coolant stored in the water tank 401 via the liquid level sensor 240a.

On the other hand, the coolant control unit 1000 obtains overall or partial leakage status of the liquid cooling device 2000 using the leakage sensor 250a. For example, sensing points P1a, P1b, P10, and P12 are disposed inside the liquid cooling device 2000, and the leakage sensor 250a detects the leakage status of the coolant according to the sensing points P1a, P1b, P10, and P12. The sensing point P1a is disposed at the outlet of the pump 130a of the pump system 100a, and the sensing point P1b is disposed at the outlet of the pump 130b of the pump system 100b. Furthermore, the sensing point P10 is disposed near the filter 404 and the filter 403, and the sensing point P12 is disposed near the water tank 401. In one example, a large leakage tray (the leakage tray is not shown in FIG. 4) may be provided at the bottom of the liquid cooling device 2000, and the leaked coolant from the pipelines of the liquid cooling device 2000 may be collected by the leakage tray. Furthermore, the leakage tray may be provided with one or more sensing points, and the coolant control unit 1000 performs leakage detection via the leakage sensor 250a (or other leakage sensors 250b and 250c) according to the sensing points or sensing lines (not shown in FIG. 4) of the leakage tray.

Please refer to FIG. 3 again to illustrate the parallel operation of the pump system 100a and the pump system 100b in the coolant control unit 1000. The pump controller 110a of the pump system 100a transmits or receives a bus signal CB1 via the bus 510, and the pump controller 110b of the pump system 100b transmits or receives a bus signal CB2 via the bus 510. The pump controller 110a and the pump controller 110b communicate with the host 500 according to the bus signal CB1 and the bus signal CB2. Furthermore, the fan controller 300a of the fan system 2001 and the fan controller 300b of the fan system 2002 communicate with the host 500 according to the bus signal CB3 and the bus signal CB4.

The bus 510 is, for example, a bus of a Controller-Area-Network (CAN), which is a bus of the "CAN-bus" type. The pump system 100a, the pump system 100b, the fan system 2001, the fan system 2002 and the host 500 communicate with one another via the bus 510 of the CAN-bus type. Based on the communication mechanism of the bus 510 of the CAN-bus type, the host 500 does not need to act as a role of a master, during the entire operation period. That is, when the host 500 is offline, the pump system 100a, the pump system 100b, the fan system 2001, and the fan system 2002 can also operate via the bus 510 of the CAN-bus type.

More specifically, the pump controller 110a, the pump controller 110b, the fan controller 300a and the fan controller 300b broadcast their respective operating state via the bus 510 within a predetermined period. Accordingly, the pump controller 110a, the pump controller 110b, the fan controller 300a and the fan controller 300b can quickly learn of the operating state of one another, and these operating states are also quickly provided to the host 500. The pump controller 110a and the pump controller 110b can quickly learn the operating state of each other via the bus 510 of the CAN-bus type, so as to implement the parallel operation mechanism. In the parallel operation mechanism, the pump system 100a and the pump system 100b can share the "load" with each other. The above-mentioned "load" refers to: the pressurization load to the coolant by the pump 130a inside the pump system 100a, and the pressurization load to the coolant by the pump 130b inside the pump system 100b. When one of the pumps 130a and 130b is in an abnormal state, the other of the pumps 130a and 130b can share the load of the abnormal operator, so that the hydraulic pressure of the coolant flowing through the pumps 130a and 130b can be kept stable, and thereby stabilizing the hydraulic pressure of the liquid cooling device 2000 and the target device 5000.

When the pump 130a and pump 130b are both in normal state, the pump 130a and pump 130b are operating concurrently. The coolant is pressurized by the pumps 130a and 130b, so that the coolant can reach a pressure balance. Furthermore, the coolant can flow in the pipeline of the liquid cooling device 2000 with a predetermined status (including, e.g., a predetermined flow rate, a predetermined flow velocity and a predetermined hydraulic pressure), so as to appropriately cool the target device 5000.

On the other hand, if one of the pumps 130a and 130b is in an abnormal state, the other one can share the load of the abnormal one. For example, when the pump 130a is in an abnormal state, the pump controller 110a for controlling the pump 130a may broadcast the bus signal CB1 via the bus 510. Furthermore, another pump controller 110b may receive the bus signal CB1 broadcasted by the pump controller 110a via the bus 510, so as to learn that the pump 130a is in an abnormal state. In response to the above situation, the pump controller 110b may control the pump 130b to increase the motor speed, so as to increase the hydraulic pressure of the coolant. Therefore, the coolant may return to a status of pressure balance, so as to maintain the normal operation of the liquid cooling device 2000. As mentioned above, the host 500 does not need to play the role of a master all the time. Even if the host 500 is offline, the pump controller 110a and the pump controller 110b can instantly know the operating state of each other via the bus 510 of the CAN-bus type, and thereby sharing the load with each other.

In addition, the pump controller 110a receives a sensing signal TS1 from the sensing module 200a. The sensing signal TS1 includes a temperature sensing result of the temperature sensor 210a of the sensing module 200a, which indicates a condition of increased liquid temperature in a certain section of the piping within the liquid cooling device 2000. The pump controller 110a can detect the condition of increased liquid temperature based on the sensing signal TS1, and transmit a corresponding bus signal CB1 to the fan controller 300a via the bus 510, so that the fan controller 300a controls the fans in the fan array 400a to increase the rotational speed, thereby improving the cooling effect of the radiator 402 of the liquid cooling device 2000, and hence overcomes the condition of increased liquid temperature.

Furthermore, the host 500 also receives the sensing signal TS3 of the sensing module 200c. The sensing signal TS3 includes the temperature sensing result of the temperature sensor 210c of the sensing module 200c, and the leakage sensing result of the leakage sensor 250c. The host 500 can also use the temperature sensor 210c to detect the temperature of the coolant. Furthermore, the host 500 can quickly learn of the leakage status of the liquid cooling device 2000 based on the leakage sensing result of the leakage sensor 250c and hence take early action accordingly.

On the other hand, in a coolant control unit of a comparative example (the structure of the coolant control unit of this comparative example is not shown), the host and multiple pump systems may operate in a master-slave mode (i.e., “mod-bus”). The host has a master role, and each of the multiple pump systems has a slave role. The host and the pump systems of this comparative example communicate with one another via a bus of “RS-485” type. When one of the pump systems of the slave role is in an abnormal status, the other pump systems cannot promptly know about the abnormal state, and therefore cannot quickly share the load of the abnormal operator. Therefore, it may lead to a hydraulic pressure imbalance of the coolant within the liquid cooling device, significantly reducing the cooling effectiveness of the coolant and resulting in overheating of the target device 5000.

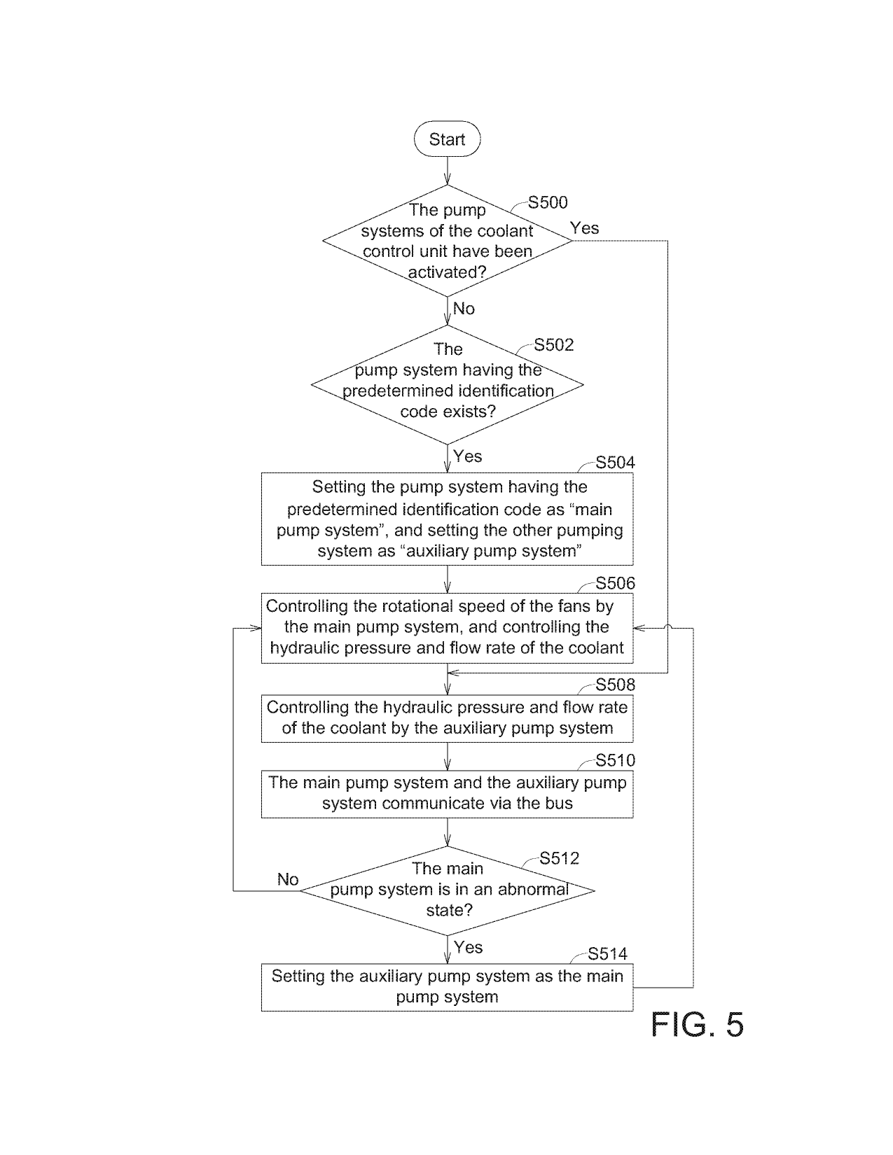

FIG. 5 is a flow chart of a control method according to an embodiment of the present disclosure. The control method of this embodiment may be applied to the coolant control unit 1000 in FIG. 3. As shown in FIG. 5, firstly, the control method starts at step S500: determining whether the pump systems of the coolant control unit 1000 have been activated. If the confirmation result is "No", step S502 is executed: checking the activated pump systems, so as to determine whether a pump system with a predetermined identification code exists. The predetermined identification code is, e.g., an identification code with the smallest number (that is, the identification code "1"). Taking the coolant control unit 1000 of FIG. 3 as an example, the pump system 100a has an identification code "1", and the pump system 100b has an identification code "2". The pump system 100a has the identification code "1" with the smallest number, which matches the predetermined identification code, and therefore the confirmation result of step S502 is "yes", then step S504 is executed.

In step S504, the pump system 100a having the predetermined identification code is set as the master role, which is referred to as a "main pump system". Furthermore, the other pump system 100b is set as an "auxiliary pump system".

Then, step S506 is executed: the pump system 100a (which serves as the main pump system) controls the fan system 2001 and the fan system 2002, so as to control the rotational speed of the fans in the fan system 2001 and the fan system 2002, and control the hydraulic pressure and flow rate of the coolant.

Then, step S508 is executed: the pump system 100b (which serves as the auxiliary pump system) controls the pump 130a and the pump 130b, so as to control the hydraulic pressure and flow rate of the coolant. Since the pump system 100b serves as the auxiliary pump system, it does not control the fan system 2001 and the fan system 2002.

Then, step S510 is executed: the pump system 100a (as the main pump system) and the pump system 100b (as the auxiliary pump system) communicate via the bus 510, so as to learn of the operating state of each other.

Then, step S512 is executed: determining whether the pump system 100a, which serves as the main pump system, is in an abnormal state. In one example, when the pump system 100a or the pump system 100b is in an abnormal state, it issues a warning signal and transmits it to the bus 510. The corresponding bus signal CB1 or bus signal CB2 may include relevant information of the warning signal. The pump system 100b, which serves as the auxiliary pump system, may analyze the bus signal CB1 of the bus 510 to determine whether the pump system 100a (which serves as the main pump system) issues a warning signal. If the confirmation result of step S512 is “Yes”, indicating that the pump system 100a (which serves as the main pump system) is in an abnormal state, step S514 is executed: the pump system 100b which originally serves as the auxiliary pump system is set as the main pump system. Then, step S506 is executed: the pump system 100b, which is newly set as the main pump system, controls the fan system 2001 and the fan system 2002.

If the confirmation result of step S512 is "No", indicating that the pump system 100a (which serves as the main pump system) has not issued a warning signal and is in a normal state, then step S506 is executed: continuing to employ the pump system 100a as the main pump system to control the fan system 2001 and the fan system 2002.

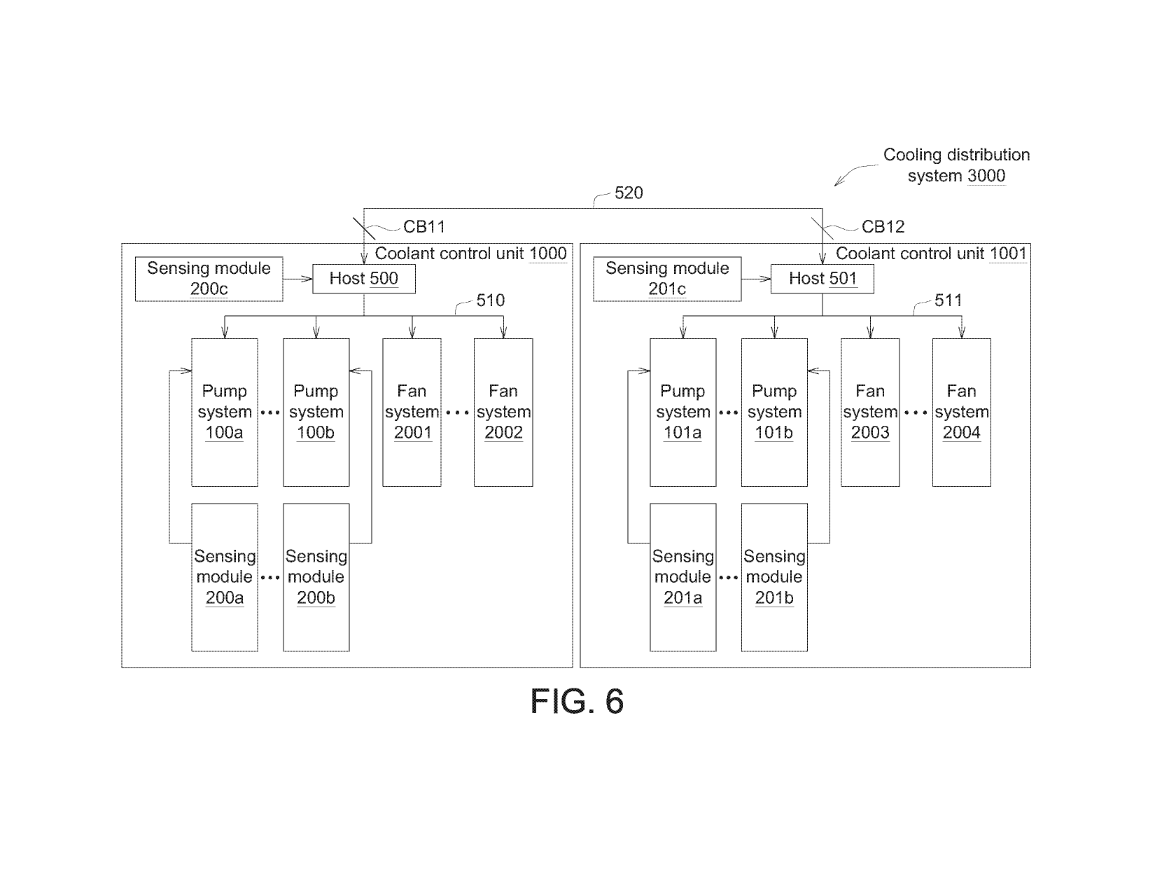

FIG. 6 is a block diagram of a cooling distribution system 3000 according to an embodiment of the present disclosure. The cooling distribution system 3000 may include several coolant control units with parallel operations. The embodiment of FIG. 6 takes two coolant control units 1000 and 1001 as examples. The coolant control unit 1000 in FIG. 6 is the coolant control unit 1000 in FIG. 3, and the other coolant control unit 1001 has the same architecture as that of the coolant control unit 1000. The coolant control unit 1001 includes a host 501, a fan system 2003, a fan system 2004, a pump system 101a, a pump system 101b, and three sensing modules 201a, 201b, and 201c.

The host 500 of the coolant control unit 1000 is coupled to the host 501 of the coolant control unit 1001 via an external bus 520. The coolant control unit 1000 communicates with the coolant control unit 1001 via the external bus 520.

Inside the coolant control unit 1000, the host 500, the fan system 2001, the fan system 2002, the pump system 100a and the pump system 100b communicate via an internal bus 510. Furthermore, inside another coolant control unit 1001, the host 501, the fan system 2003, the fan system 2004, the pump system 101a and the pump system 101b communicate via the internal bus 511.

The above-mentioned buses 510, 511 and 520 all have a type of CAN-bus. The host 500 of the coolant control unit 1000 transmits or receives a bus signal CB11 via the bus 520, and the host 501 of the coolant control unit 1001 transmits or receives a bus signal CB12 via the bus 520. By means of bus signals CB11 and CB12, the host 500 of the coolant control unit 1000 and the host 501 of the coolant control unit 1001 can broadcast their respective operating states via the bus 520. Accordingly, the host 500 of the coolant control unit 1000 and the host 501 of the coolant control unit 1001 can quickly learn of the operating state of each other, thereby achieving the effect of parallel operation.

It will be apparent to those skilled in the art that various modifications and variations can be made to the disclosed embodiments. It is intended that the specification and examples be considered as exemplars only, with a true scope of the disclosure being indicated by the following claims and their equivalents.

What is claimed is:

1. A coolant control unit, for controlling a liquid cooling device to cool a target device, the coolant control unit comprising:
a first pump system, coupled to a bus of a Controller-Area-Network (CAN) type, and for transmitting or receiving a first bus signal via the bus, wherein a first pump of the first pump system causes a coolant of the liquid cooling device to have a first hydraulic pressure; and
a second pump system, coupled to the first pump system via the bus, and for transmitting or receiving a second bus signal via the bus, wherein a second pump of the second pump system causes the coolant to have a second hydraulic pressure,
wherein the first bus signal and the second bus signal respectively indicate an abnormal state of the first pump system and an abnormal state of the second pump system.

2. The coolant control unit of claim 1, wherein the first pump system has a predetermined identification code, the first pump system is set as a main pump system, and the second pump system is set as an auxiliary pump system.

3. The coolant control unit of claim 2, wherein when the first pump system is in the abnormal state, the second pump system is set as the main pump system.

4. The coolant control unit of claim 2, further comprising:
a first fan system, comprising a first fan array; and
a second fan system, comprising a second fan array,
wherein the main pump system controls rotational speeds of a plurality of fans in the first fan array and the second fan array.

5. The coolant control unit of claim 2, wherein the main pump system and the auxiliary pump system control the first pump and the second pump to adjust the first hydraulic pressure and the second hydraulic pressure of the coolant respectively.

6. The coolant control unit of claim 1, further comprising:
a first sensing module, coupled to the first pump system; and
a second sensing module, coupled to the second pump system,
wherein each of the first sensing module and the second sensing module comprises a temperature sensor, a pressure sensor, a flow rate sensor, a liquid level sensor and a leakage sensor.

7. The coolant control unit of claim 6, further comprising:
a host, coupled to the first pump system and the second pump system via the bus, and the host transmits or receives the first bus signal and the second bus signal via the bus; and
a third sensing module, directly coupled to the host.

8. The coolant control unit of claim 6, wherein the liquid cooling device comprising:
a water tank, for storing the coolant,
wherein a first liquid level sensor of the first sensing module or a second liquid level sensor of the second sensing module is used to detect a liquid level of the coolant in the water tank.

9. The coolant control unit of claim 6, wherein the liquid cooling device further comprising:
a first pipeline, provided with the first pump, and the coolant flowing through the first pipeline has the first hydraulic pressure; and
a second pipeline, provided with the second pump, and the coolant flowing through the second pipeline has the second hydraulic pressure,
wherein a first pressure sensor of the first sensing module is used to detect the first hydraulic pressure, and a second pressure sensor of the second sensing module is used to detect the second hydraulic pressure.

10. The coolant control unit of claim 9, wherein the coolant flowing through the first pipeline has a first liquid temperature, the coolant flowing through the second pipeline has a second liquid temperature, a first temperature sensor of the first sensing module is used to detect the first liquid temperature, and a second temperature sensor of the second sensing module is used to detect the second liquid temperature.

11. The coolant control unit of claim 9, wherein a first leakage sensor of the first sensing module and a second leakage sensor of the second sensing module are respectively used to detect a leakage status of the first pipeline and the second pipeline.

12. A control method for a coolant control unit, wherein the coolant control unit controls a liquid cooling device to cool a target device, a first pump system of the coolant control unit is coupled to a bus of a Controller-Area-Network (CAN) type, and a second pump system of the coolant control unit is coupled to the first pump system via the bus, the control method comprising:
pressurizing a coolant of the liquid cooling device by a first pump of the first pump system to cause the coolant having a first hydraulic pressure;
pressurizing the coolant by a second pump of the second pump system to cause the coolant having a second hydraulic pressure;
transmitting or receiving a first bus signal via the bus by the first pump system; and
transmitting or receiving a second bus signal via the bus by the second pump system,
wherein the first bus signal and the second bus signal respectively indicate an abnormal state of the first pump system and an abnormal state of the second pump system.

13. The control method of claim 12, wherein the first pump system has a predetermined identification code, and the control method further comprising:
setting the first pump system as a main pump system; and
setting the second pump system as an auxiliary pump system.

14. The control method of claim 13, wherein when the first pump system is in an abnormal state, the control method further comprising:
setting the second pump system as the main pump system.

15. The control method of claim 13, wherein the coolant control unit further comprises a first fan system and a second fan system, the first fan system comprises a first fan array, the second fan system comprises a second fan array, and the control method further comprising:
controlling the rotational speeds of the plurality of fans in the first fan array and the second fan array by the main pump system.

16. The control method of claim 13, further comprising:
controlling the first pump and the second pump to adjust the first hydraulic pressure and the second hydraulic pressure of the coolant respectively, by the main pump system and the auxiliary pump system.

17. The control method of claim 12, wherein the coolant control unit further comprises a first sensing module and a second sensing module, the first sensing module is coupled to the first pump system, and the second sensing module is coupled to the second pump system,
wherein each of the first sensing module and the second sensing module comprises a temperature sensor, a pressure sensor, a flow rate sensor, a liquid level sensor and a leakage sensor.

18. The control method of claim 17, wherein the coolant control unit further comprises a host and a third sensing module, the host is coupled to the first pump system and the second pump system via the bus, and the third sensing module is directly coupled to the host, and the control method further comprising:
transmitting or receiving the first bus signal and the second bus signal via the bus, by the host.

19. The control method of claim 17, wherein the liquid cooling device comprises a water tank for storing the coolant, and the control method further comprising:
sensing a liquid level of the coolant in the water tank by a first liquid level sensor of the first sensing module or a second liquid level sensor of the second sensing module.

20. The control method of claim 17, wherein the liquid cooling device further comprises a first pipeline and a second pipeline, the first pipeline and the second pipeline are respectively provided with the first pump and the second pump, the coolant flowing through the first pipeline has the first hydraulic pressure, the coolant flowing through the second pipeline has the second hydraulic pressure, and the control method further comprising:
sensing the first hydraulic pressure by a first pressure sensor of the first sensing module; and
sensing the second hydraulic pressure by a second pressure sensor of the second sensing module.
